(19) United States
(12) Patent Application Publication
(10) Pub. No.: US 2017/0168641 A1
(43) Pub. Date: Jun. 15, 2017

(54) DISPLAY DEVICE WITH FORCE SENSING DEVICE

(71) Applicant: Novatek Microelectronics Corp., Hsinchu (TW)

(72) Inventors: Chih-Jen Cheng, Hsinchu City (TW); Yu-Ying Tang, Taoyuan City (TW); Kuan-Yi Yang, Taipei City (TW)

(73) Assignee: Novatek Microelectronics Corp., Hsinchu (TW)

(21) Appl. No.: 15/373,488

(22) Filed: Dec. 9, 2016

Related U.S. Application Data
(60) Provisional application No. 62/265,997, filed on Dec. 11, 2015.

(51) Int. Cl. G06F 3/041; G02F 1/1368; H01L 51/52; H01L 51/50; H01L 27/32; G06F 3/044; G02F 1/1343

(52) U.S. Cl. CPC G06F 3/0416; G06F 3/044; G02F 1/1368; G02F 1/134363; H01L 51/5012; H01L 27/322; H01L 51/5271; G06F 2203/04105

(57) ABSTRACT

A display device with a force sensing device is provided. The display device with the force sensing device includes a display layer and a non-display layer. The display layer is configured to display an image. The non-display layer is disposed below the display layer. The non-display layer includes a first signal transmission layer and a first signal transmission layer. The deformable layer is disposed on a surface of the first signal transmission layer. The force sensing device includes the deformable layer, the first signal transmission layer and a second signal transmission layer. The second signal transmission layer is disposed above the first signal transmission layer. One of the first signal transmission layer and the second signal transmission layer receives a driving signal and the other of the first signal transmission layer and the second signal transmission layer receives a sensing signal.

### CROSS-REFERENCE TO RELATED APPLICATION

This application claims the priority benefits of U.S. provisional application Ser. No. 62/265,997, filed on Dec. 11, 2015. The entirety of the above-mentioned patent application is hereby incorporated by reference herein and made a part of this specification.

### BACKGROUND OF THE INVENTION

1. Field of the Invention

The invention generally relates to a display device, in particular, to a display device with a force sensing device.

2. Description of Related Art

In this information era, reliance on electronic products is increasing day by day. The electronic products including notebook computers, mobile phones, personal digital assistants (PDAs), digital walkmans, and so on are indispensable in our daily lives. Each of the aforesaid electronic products has an input interface for a user to input his or her command, such that an internal system of each of the electronic product spontaneously runs the command. At this current stage, the most common input interface includes a keyboard and a mouse.

From the user's aspect, it is sometimes rather inconvenient to use the conventional input interface including the keyboard and the mouse. Manufacturers aiming to resolve said issue thus start to equip the electronic products with touch input interfaces, e.g. touch pads or touch panels, and force sensing devices, so as to replace the conditional keyboards and mice. At present, the users' commands are frequently given to the electronic products by physical contact, sensing relationship between users' fingers or styluses and the touch input interfaces, or sensing forces of users applied to the electronic products. In some applications, the force sensing devices are integrated into display devices to provide a good user experience.

### SUMMARY OF THE INVENTION

Accordingly, the invention is directed to a display device having a force sensing device capable of sensing a force applied to the display device.

An embodiment of the invention provides a display device with a force sensing device. The display device with the force sensing device includes a display layer and a non-display layer. The display layer is configured to display an image. The non-display layer is disposed below the display layer. The non-display layer includes a first signal transmission layer and a first signal transmission layer. The deformable layer is disposed on a surface of the first signal transmission layer. The force sensing device includes the deformable layer, the first signal transmission layer and a second signal transmission layer. The second signal transmission layer is disposed above the first signal transmission layer. One of the first signal transmission layer and the second signal transmission layer receives a driving signal and the other of the first signal transmission layer and the second signal transmission layer receives a sensing signal.

In an embodiment of the invention, the second signal transmission layer is disposed inside one of the display layer and the non-display layer.

In an embodiment of the invention, the deformable layer is disposed inside the non-display layer or between the display layer and the non-display layer.

In an embodiment of the invention, the display layer includes a substrate and a transistor circuit layer. The transistor circuit layer is disposed above the substrate. The transistor circuit layer serves as the second signal transmission layer.

In an embodiment of the invention, the display layer includes a liquid crystal layer. The display layer is driven by a horizontal electrical field.

In an embodiment of the invention, the non-display layer includes a backlight frame and a backlight module. The backlight module is disposed above the backlight frame and includes a reflector. The first signal transmission layer is the backlight frame or the reflector.

In an embodiment of the invention, the deformable layer is disposed between the reflector and the backlight frame.

In an embodiment of the invention, the non-display layer further includes a backlight frame which the first signal transmission layer is disposed above and a backlight module. The backlight module is disposed above the first signal transmission layer and includes a reflector.

In an embodiment of the invention, the deformable layer is disposed between the substrate and the backlight module or between the reflector and the first signal transmission layer.

In an embodiment of the invention, the display layer further includes one of a liquid crystal layer and an organic electro-luminescence layer.

In an embodiment of the invention, the non-display layer includes a backlight frame, an electrode layer and a backlight module. The electrode layer is disposed above the backlight frame. The backlight module is disposed above the electrode layer and includes a reflector. The first signal transmission layer and the second signal transmission layer are selected from two of the reflector, the electrode layer and the backlight frame.

In an embodiment of the invention, the electrode layer serves as the first signal transmission layer. The reflector serves as the second signal transmission layer. The deformable layer is disposed between the reflector and the electrode layer.

In an embodiment of the invention, the electrode layer serves as the first signal transmission layer. The reflector serves as the second signal transmission layer. The deformable layer is disposed between the electrode layer and the backlight frame.

An embodiment of the invention provides a display device with a force sensing device. The display device with the force sensing device includes a display layer and a non-display layer. The display layer is configured to display an image. The non-display layer is disposed below the display layer. The non-display layer includes a deformable layer. The force sensing device includes the deformable layer, a signal transmission layer and a reference layer. The deformable layer is disposed on a surface of the signal transmission layer. The signal transmission layer is configured to receive a driving signal and receive a sensing signal. The reference layer is configured to provide a reference voltage level.

In an embodiment of the invention, the signal transmission layer is disposed inside one of the display layer and the non-display layer.

In an embodiment of the invention, the deformable layer is disposed inside the non-display layer or between the display layer and the non-display layer.

In an embodiment of the invention, the reference layer is disposed inside one of the display layer and the non-display layer.

In an embodiment of the invention, the display layer includes a substrate and a transistor circuit layer. The transistor circuit layer is disposed above the substrate. The transistor circuit layer serves as the signal transmission layer.

In an embodiment of the invention, the display layer includes a liquid crystal layer. The display layer is driven by a horizontal electrical field.

In an embodiment of the invention, the non-display layer includes a backlight frame and a backlight module. The backlight module is disposed above the backlight frame and includes a reflector. The backlight frame or the reflector servers as the reference layer.

In an embodiment of the invention, the deformable layer is disposed between the reflector and the backlight frame.

In an embodiment of the invention, the non-display layer further includes a backlight frame which the reference layer is disposed above and a backlight module. The backlight module is disposed above the reference layer and includes a reflector.

In an embodiment of the invention, the deformable layer is disposed between the substrate and the backlight module or between the reflector and the reference layer.

In an embodiment of the invention, the display layer further includes one of a liquid crystal layer and an organic electro-luminescence layer.

In an embodiment of the invention, the non-display layer includes a backlight frame, an electrode layer and a backlight module. The electrode layer is disposed above the backlight frame. The backlight module is disposed above the electrode layer and includes a reflector. The reference layer and the signal transmission layer are two of the reflector, the electrode layer and the backlight frame.

In an embodiment of the invention, the electrode layer serves as the reference layer. The reflector serves as the signal transmission layer. The deformable layer is disposed between the reflector and the electrode layer.

In an embodiment of the invention, the electrode layer serves as the reference layer. The reflector serves as the signal transmission layer. The deformable layer is disposed between the electrode layer and the backlight frame.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A illustrates a schematic diagram of a display device with a force sensing device according to an embodiment of the invention.

FIG. 1B illustrates a schematic diagram of a display device with a force sensing device according to another embodiment of the invention.

FIG. 2A illustrates a schematic diagram of a display device with a force sensing device according to another embodiment of the invention.

FIG. 2B illustrates a schematic diagram of a display device with a force sensing device according to another embodiment of the invention.

FIG. 3A illustrates a schematic diagram of a display device with a force sensing device according to another embodiment of the invention.

FIG. 3B illustrates a schematic diagram of a display device with a force sensing device according to another embodiment of the invention.

FIG. 4A illustrates a schematic diagram of a display device with a force sensing device according to another embodiment of the invention.

FIG. 4B illustrates a schematic diagram of a display device with a force sensing device according to another embodiment of the invention.

FIG. 5A illustrates a schematic diagram of a display device with a force sensing device according to another embodiment of the invention.

FIG. 5B illustrates a schematic diagram of a display device with a force sensing device according to another embodiment of the invention.

FIG. 6A illustrates a schematic diagram of a display device with a force sensing device according to another embodiment of the invention.

FIG. 6B illustrates a schematic diagram of a display device with a force sensing device according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts. The terms used herein such as “above”, “below”, “front”, “back”, “left” and “right” are for the purpose of describing directions in the figures only and are not intended to be limiting of the invention.

In exemplary embodiments of the invention, the display device may be a flat panel display, a curved panel display or a 3D display, including Liquid Crystal Display (LCD), Plasma Display Panel (PDP), Organic Light Emitting Display (OLED), Field Emission Display (FED), Electro-Phoretic Display (EPD) or Light Emitting Diode Display and the like, which are not limited by the invention. In the following description, LCD and OLED are taken for example, and the display devices of other types can be deduced by analogy.

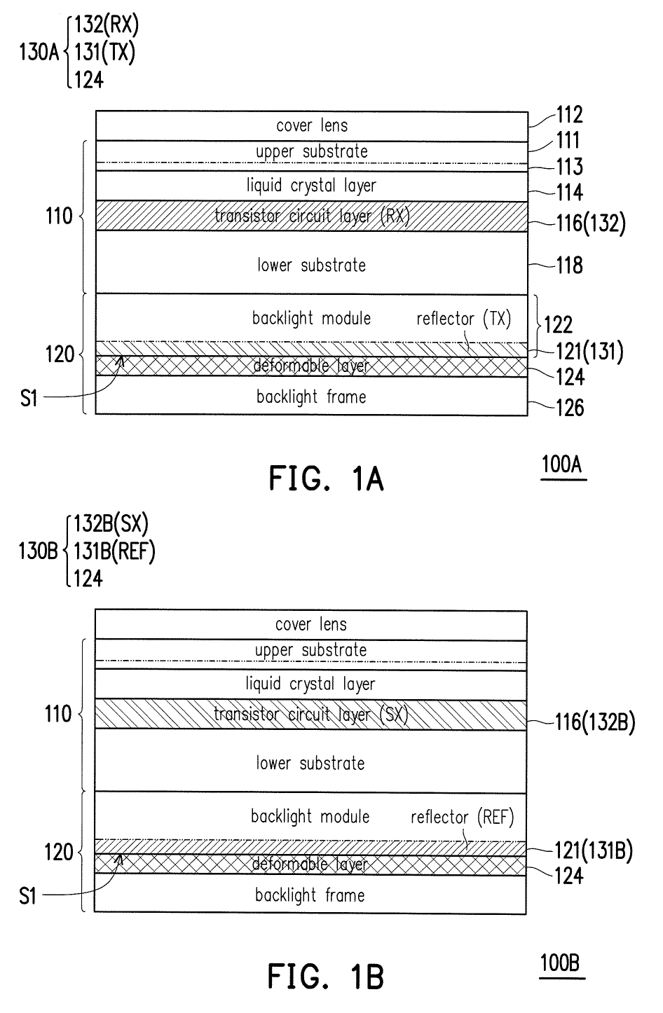

FIG. 1A illustrates a schematic diagram of a display device with a force sensing device according to an embodiment of the invention. Referring to FIG. 1A, the display device 100A of the present embodiment has a mutual capacitance type force sensing device and includes a display layer 110 and a non-display layer 120. The non-display layer 120 is disposed below the display layer 110. The display layer 110 is configured to display an image. The display device 100A may include a cover lens 112 disposed above the display layer 110 to protect the display layer 110 from being damaged. In the present embodiment, the display layer 110 is driven by the horizontal electrical field, such as in a manner of in-plane-switching (IPS), fringe field switching (FFS), etc.

In the present embodiment, the display layer 110 includes an upper substrate 111, a color filter layer 113 formed on the upper substrate 111, a lower substrate 118, a transistor circuit layer 116 formed on the lower substrate 118, and a liquid crystal layer 114 disposed between the color filter layer 111 and the transistor circuit layer 116. In an embodiment, the display layer 110 may include an organic electro-luminescence layer for image display instead of the liquid crystal layer. The structure of the display layer 110 is, from bottom to top, the lower substrate 118 (as the bottom layer), the transistor circuit layer 116, the liquid crystal layer 114, the color filter layer 113, and the upper substrate 111 (as the top layer). In the present embodiment, the upper substrate 111 and the lower substrate 118 may be glass substrates or light-transmissive substrates, and the invention is not limited thereto. In an embodiment, the display layer 110 may further include other suitable elements such as polarizers, and the invention is not limited thereto. The transistor circuit layer 116 may include common electrodes, pixel electrodes, source line electrodes, gate line electrodes, or other electrically conductive lines.

In the present embodiment, the non-display layer 120 includes a backlight module 122, a deformable layer 124 and a backlight frame 126. The backlight module 122 includes a reflector 121 as a reflector sheet. In an embodiment, the backlight module 122 may further include other suitable elements such as a polarizer sheet, a prism sheet, a diffuser sheet, or a light guide panel, and the invention is not limited thereto. The deformable layer 124 is disposed above the backlight frame 126. The backlight module 122 is disposed above the deformable layer 124. In the present embodiment, the display device 100A may be applied to a mobile device or other similar devices. The mobile device may include a middle frame to support elements disposed thereon such as a battery, a motherboard or a device case. The backlight module 122 of the display device 100A may be disposed above the middle frame of the mobile device.

In the present embodiment, the display device 100A includes a force sensing device 130A. The force sensing device 130A is configured to sense a force applied to the display device 100A. The force sensing device 130A is a mutual capacitance type force sensing device and includes a first signal transmission layer 131, a second signal transmission layer 132 and the deformable layer 124. The second signal transmission layer 132 is disposed above the first signal transmission layer 131. For force sensing operation, a driver and/or a controller may transmit a driving signal to a driving electrode layer (or called a transmitting electrode layer, denoted TX) of the force sensing device 130A such as one of the first signal transmission layer 131 and the second signal transmission layer 132. The force sensing device 130A is driven to sense the force applied to the display device 100A. When the force is applied to the display device 100A, the deformable layer 124 is deformed, and a capacitance between the first signal transmission layer 131 and the second signal transmission layer 132 may change. A sensing signal indicating capacitance difference information is generated and received by a sensing electrode layer (or called a receiving electrode layer, denoted RX) of the force sensing device 130A such as the other of the first signal transmission layer 131 and the second signal transmission layer 132.

In the present embodiment, the first signal transmission layer 131 is disposed inside the non-display layer 120 and above the backlight frame 126, and the second signal transmission layer 132 is disposed inside the display layer 110. The reflector 121 serves as the first signal transmission layer 131, and receives the driving signal. The driving signal is transmitted in the first signal transmission layer 131. The driving signal drives the force sensing device 130A to sense the force applied to the display device 100A. In the present embodiment, the force sensing device 130A is driven to sense the force applied to the display device 100A, and generates a sensing signal. The transistor circuit layer 116 serves as the second signal transmission layer 132, and receives the sensing signal. The sensing signal is transmitted in the second signal transmission layer 132. In an embodiment, the sensing signal may be transmitted in common electrodes of the transistor circuit layer 116.

In the present embodiment, the deformable layer 124 may be deformed by the force applied to the display device 100A. The deformable layer 124 is disposed inside the non-display layer 120 and between the backlight frame 126 and the backlight module 122. The deformable layer 124 is disposed on a lower surface S1 of the first signal transmission layer 131, i.e. the reflector 121. The deformable layer 124 is selected from an air gap, an elastic cushion layer, and any other suitable means which is deformed when the force is applied to the display device 100A. In another embodiment, the deformable layer may be disposed on an upper surface of the first signal transmission layer. In another embodiment, the sensing signal is transmitted in the first signal transmission layer 131 and the driving signal is transmitted in the second signal transmission layer 132; in other words, the reflector 121 may serve as the first signal transmission layer 131 and receive the sensing signal as a sensing electrode layer (RX), and the transistor circuit layer 116 may serve as the second signal transmission layer 132 and receive the driving signal as a driving electrode layer (TX). In such a case, the driving signal may be transmitted in common electrodes, source line electrodes, gate line electrodes or other electrically conductive lines of the transistor circuit layer 116, and the reflector 121 may be divided into a plurality of sensing regions. In brief, one of the transistor circuit layer 116 and the reflector 121 serves as the driving electrode layer and the other servers as the sensing electrode layer, or vice versa.

FIG. 1B illustrates a schematic diagram of a display device with a force sensing device according to another embodiment of the invention. Referring to FIG. 1B, in the present embodiment, a force sensing device 130B is a self-capacitance type force sensing device and includes a reference layer 131B, the signal transmission layer 132B and the deformable layer 124. The signal transmission layer 132B of the self-capacitance type force sensing device 130B is configured to receive a driving signal and a sensing signal as a sensor electrode layer. The reference layer 131B is configured to provide a reference voltage level, such as a ground level. The sensing signal indicates a capacitance difference between the signal transmission layer 132B and the reference layer 131B generated when a force is applied to the display device 100B. The deformable layer 124 is disposed on the lower surface S1 of the reference layer 131B. The display device 100B of the present embodiment is similar to the display device 100A depicted in FIG. 1A, and the main difference therebetween, for example, lies in that the reflector 121 serves as the reference layer (REF), and the transistor circuit layer 116 serves as the signal transmission layer 132B receiving the driving signal and receiving the sensing signal, as a sensor electrode layer (SX). In the present embodiment, the driving signal and the sensing signal may be transmitted in common electrode of the transistor circuit layer 116. Besides, the structure of the display device 100B described in this embodiment of the invention is sufficiently taught, suggested, and embodied in the embodiment illustrated in FIG. 1A, and therefore no further description is provided herein. In another embodiment, the reflector 121 may serve as the signal transmission layer 132B and receives the driving signal and the sensing signal, as the sensor electrode layer (SX), and the transistor circuit layer 116 may serves as the reference layer (REF) providing a reference voltage level. In such a case, the reflector 121 served as the sensor electrode layer may be divided into a plurality of sensing regions. When the force is applied to the display device 100B, the deformable layer 124 is deformed, and a capacitance between the signal transmission layer 132B and the reference layer 131B may change. A sensing signal indicating capacitance difference information is generated and received by the signal transmission layer 132B.

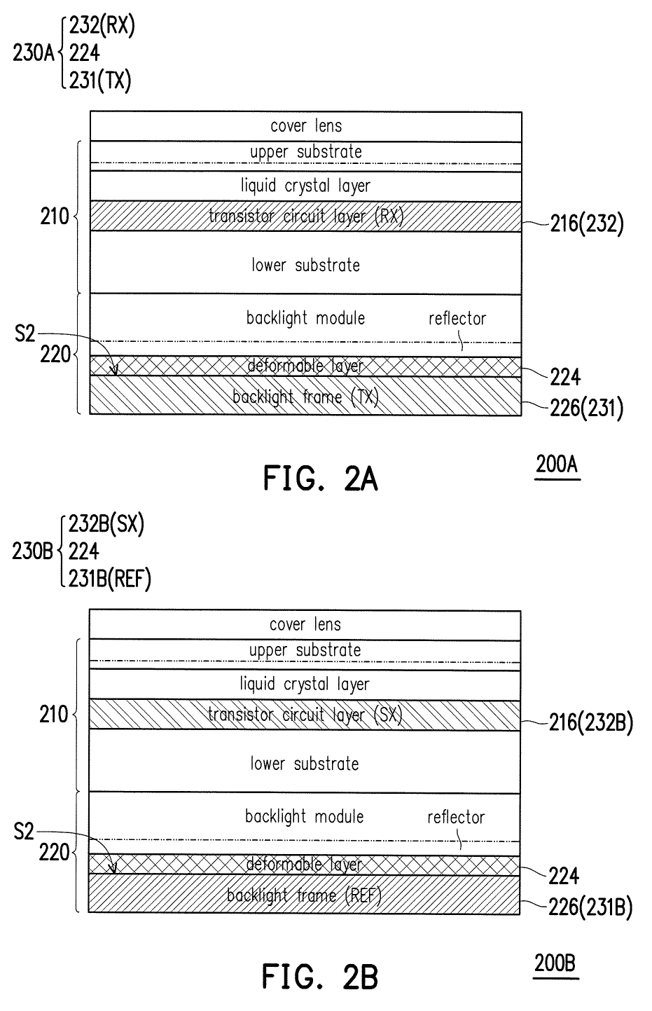

FIG. 2A illustrates a schematic diagram of a display device with a force sensing device according to another embodiment of the invention. Referring to FIG. 2A, in the present embodiment, a display device 200A includes a display layer 210 and a non-display layer 220, and a force sensing device 230A is a mutual capacitance type force sensing device and includes a first signal transmission layer 231, a second signal transmission layer 232 and a deformable layer 224. The deformable layer 224 is disposed on an upper surface S2 of the first signal transmission layer 231. In the present embodiment, the first signal transmission layer 231 is disposed inside the non-display layer 220, and the second signal transmission layer 232 is disposed inside the display layer 210. In the present embodiment, the display layer 210 is driven by the horizontal electrical field, such as in a manner of in-plane-switching (IPS) or fringe field switching (FFS). The display device 200A of the present embodiment is similar to the display device 100A depicted in FIG. 1A, and the main difference therebetween, for example, lies in that the backlight frame 226 serves as the first signal transmission layer 231, and receives the driving signal. The transistor circuit layer 216 serves as the second signal transmission layer 232 and receives the sensing signal. In other words, the backlight frame 226 servers as a driving electrode layer (TX) and the transistor circuit layer 216 serves as a sensing electrode layer (RX). In the present embodiment, the sensing signal may be transmitted in common electrodes of the transistor circuit layer 216. In another embodiment, the sensing signal is transmitted in the first signal transmission layer 231 and the driving signal is transmitted in the second signal transmission layer 232; in other words, the backlight frame 226 may serve as the first signal transmission layer 231 and receive the sensing signal as a sensing electrode layer (RX), and the transistor circuit layer 216 may serve as the second signal transmission layer 232 and receive the driving signal as a driving electrode layer (TX). In such as case, the driving signal may be transmitted in common electrodes, source line electrodes, gate line electrodes or other electrically conductive lines of the transistor circuit layer 216, and the backlight frame 226 served as the sensing electrode layer may be divided into a plurality of sensing regions. In a brief, one of the transistor circuit layer 216 and the backlight frame 226 serves as the driving electrode layer and the other servers as the sensing electrode layer, or vice versa. Besides, the structure of the display device 200A described in this embodiment of the invention is sufficiently taught, suggested, and embodied in the embodiments illustrated in FIG. 1A to FIG. 1B, and therefore no further description is provided herein.

FIG. 2B illustrates a schematic diagram of a display device with a force sensing device according to another embodiment of the invention. Referring to FIG. 2B, in the present embodiment, a force sensing device 230B is a self-capacitance type force sensing device and includes a reference layer 231B, the signal transmission layer 232B and the deformable layer 224. The signal transmission layer 232B of the self-capacitance type force sensing device 230B is configured to receive a driving signal and a sensing signal as a sensor electrode layer. The reference layer 231B is configured to provide a reference voltage level, such as a ground level. The sensing signal indicates a capacitance difference between the signal transmission layer 232B and the reference layer 231B generated when a force is applied to the display device 200B. The deformable layer 224 is disposed on the upper surface S2 of the signal transmission layer 231B. The display device 200B of the present embodiment is similar to the display device 200A depicted in FIG. 2A, and the main difference therebetween, for example, lies in that the backlight frame 226 serves as the reference layer (REF), and the transistor circuit layer 216 serves as the signal transmission layer 232B receiving the driving signal and receiving the sensing signal, as a sensor electrode layer (SX). In the present embodiment, the driving signal and the sensing signal may be transmitted in common electrode of the transistor circuit layer 216. Besides, the structure of the display device 200B described in this embodiment of the invention is sufficiently taught, suggested, and embodied in the embodiments illustrated in FIG. 1A to FIG. 2A, and therefore no further description is provided herein. In another embodiment, the backlight frame 226 may serve as the signal transmission layer 232B and receives the driving signal and the sensing signal, as a sensor electrode layer (SX), and the transistor circuit layer 216 may serves as the reference layer 131B (REF) providing a reference voltage level. In such as case, the backlight frame 226 may be divided into a plurality of sensing regions. When the force is applied to the display device 200B, the deformable layer 224 is deformed, and a capacitance between the signal transmission layer 232B and the reference layer 231B may change. A sensing signal indicating capacitance difference information is generated and received by the signal transmission layer 232B.

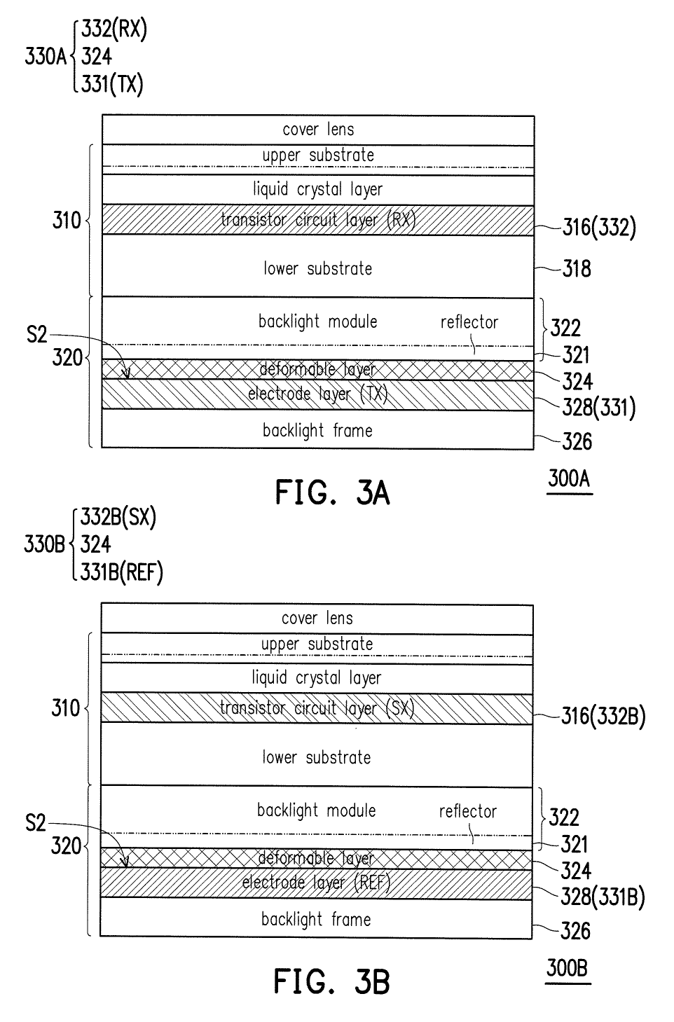

FIG. 3A illustrates a schematic diagram of a display device with a force sensing device according to another embodiment of the invention. Referring to FIG. 3A, in the present embodiment, a display device 300A includes a display layer 310 and a non-display layer 320, and a force sensing device 330A is a mutual capacitance type force sensing device and includes a first signal transmission layer 331, a second signal transmission layer 332 and a deformable layer 324. The deformable layer 324 is disposed on an upper surface S2 of the first signal transmission layer 331. In the present embodiment, the first signal transmission layer 331 is disposed inside the non-display layer 320, and the second signal transmission layer 332 is disposed inside the display layer 310. In the present embodiment, the display layer 310 is driven by the horizontal electrical field, such as in a manner of in-plane-switching (IPS) or fringe field switching (FFS). The display device 300A of the present embodiment is similar to the display device 100A depicted in FIG. 1A, and the main difference therebetween, for example, lies in that the non-display layer 320 further includes an electrode layer 328. The electrode layer 328 is disposed above a backlight frame 326. In the present embodiment, not a reflector 321 but the electrode layer 328 serves as the first signal transmission layer 331, and receives the driving signal. A transistor circuit layer 316 of the display layer 310 serves as the second signal transmission layer 332 and receives the sensing signal. In other words, the electrode layer 328 servers as a driving electrode layer (TX) and the transistor circuit layer 316 serves as a sensing electrode layer (RX). In the present embodiment, the sensing signal may be transmitted in common electrodes of the transistor circuit layer 316.

In the present embodiment, the first signal transmission layer 331 disposed above the backlight frame 326, and a backlight module 322 including the reflector 321 is disposed above the first signal transmission layer 331. In the present embodiment, the deformable layer 324 is disposed between the reflector 321 and the first signal transmission layer 331, but the invention is not limited thereto. In another embodiment, the deformable layer 324 may be disposed between a lower substrate 318 of the display layer 310 and the backlight module 322. Besides, the structure of the display device 300A described in this embodiment of the invention is sufficiently taught, suggested, and embodied in the embodiments illustrated in FIG. 1A to FIG. 2B, and therefore no further description is provided herein. In another embodiment, the sensing signal is transmitted in the first signal transmission layer 331 and the driving signal is transmitted in the second signal transmission layer 332; in other words, the electrode layer 328 may serve as the first signal transmission layer 331 and receive the sensing signal as a sensing electrode layer (RX) and may be divided into a plurality of sensing regions, and the transistor circuit layer 316 may serve as the second signal transmission layer 332 and receive the driving signal as a driving electrode layer (TX). In a brief, one of the transistor circuit layer 316 and the electrode layer 328 serves as the driving electrode layer and the other servers as the sensing electrode layer, or vice versa.

FIG. 3B illustrates a schematic diagram of a display device with a force sensing device according to another embodiment of the invention. Referring to FIG. 3B, in the present embodiment, a force sensing device 330B is a self-capacitance type force sensing device and includes a reference layer 331B, the signal transmission layer 332B and the deformable layer 324. The signal transmission layer 332B of the self-capacitance type force sensing device 330B is configured to receive a driving signal and a sensing signal as a sensor electrode layer. The reference layer 331B is configured to provide a reference voltage level, such as a ground level. The sensing signal indicates a capacitance difference between the signal transmission layer 332B and the reference layer 331B generated when a force is applied to the display device 300B. The deformable layer 324 is disposed on the upper surface S2 of the first signal transmission layer 331. The display device 300B of the present embodiment is similar to the display device 300A depicted in FIG. 3A, and the main difference therebetween, for example, lies in that, the electrode layer 328 serves as the reference layer (REF), and the transistor circuit layer 316 serves as the signal transmission layer 332B receiving the driving signal and receiving the sensing signal, as a sensor electrode layer (SX). In the present embodiment, the driving signal and the sensing signal may be transmitted in common electrode of the transistor circuit layer 316. Besides, the structure of the display device 300B described in this embodiment of the invention is sufficiently taught, suggested, and embodied in the embodiments illustrated in FIG. 1A to FIG. 3A, and therefore no further description is provided herein. In another embodiment, the electrode layer 328 may serve as the signal transmission layer 332B and receives the driving signal and the sensing signal, as a sensor electrode layer (SX), and the transistor circuit layer 316 may serves as the reference layer 331B (REF) providing a reference voltage level. In such as case, the electrode layer 328 may be divided into a plurality of sensing regions.

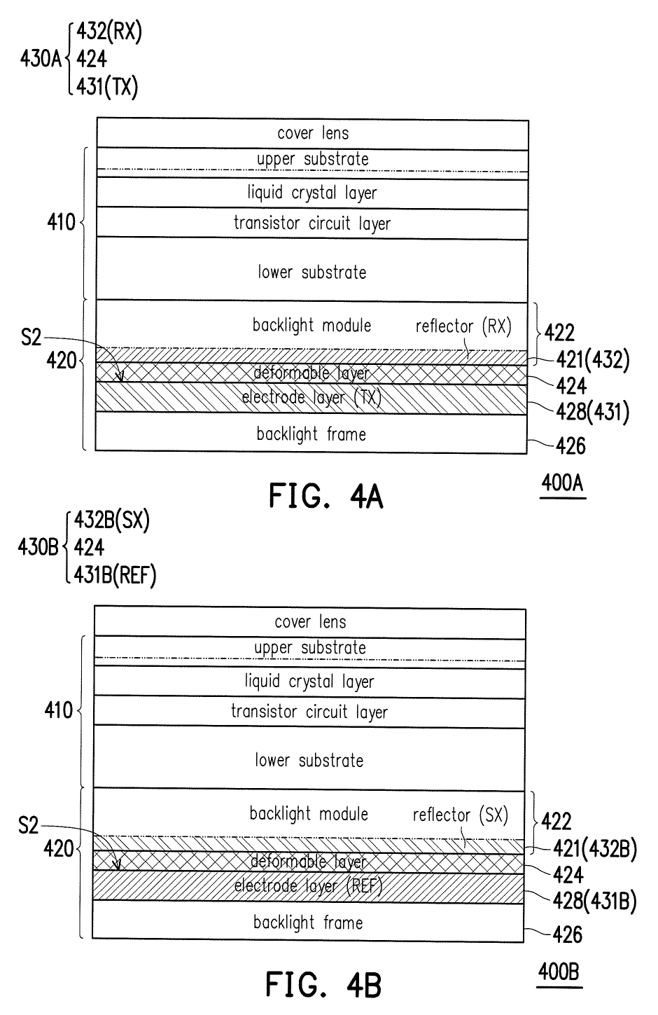

FIG. 4A illustrates a schematic diagram of a display device with a force sensing device according to another embodiment of the invention. Referring to FIG. 4A, in the present embodiment, a display device 400A includes a display layer 410 and a non-display layer 420, and a force sensing device 430A is a mutual capacitance type force sensing device and includes a first signal transmission layer 431, a second signal transmission layer 432 and a deformable layer 424. The first signal transmission layer 431 and the second signal transmission layer 432 are disposed inside the non-display layer 420. In the present embodiment, the driving type of the display layer 410 may be the horizontal electrical field driving or the vertical electrical field driving. The deformable layer 424 is disposed on an upper surface S2 of the first signal transmission layer 431. In the non-display layer 420, an electrode layer 428 is disposed between the deformable layer 424 and a backlight frame 426. The deformable layer 424 is disposed between a reflector 421 of a backlight module 422 and the electrode layer 428. The reflector 421 serves as the second signal transmission layer 432 and receives the sensing signal. The electrode layer 428 serves as the first signal transmission layer 431 and receives the driving signal. In other words, the reflector 421 servers as a sensing electrode layer (RX) and the electrode layer 428 serves as a driving electrode layer (TX). The reflector 421 served as the sensing electrode layer may be divided into a plurality of sensing regions. Besides, the structure of the display device 400A described in this embodiment of the invention is sufficiently taught, suggested, and embodied in the embodiments illustrated in FIG. 1A to FIG. 3B, and therefore no further description is provided herein. In another embodiment, the sensing signal is transmitted in the first signal transmission layer 431 and the driving signal is transmitted in the second signal transmission layer 432; in other words, the electrode layer 428 may serve as the first signal transmission layer 431 and receive the sensing signal as a sensing electrode layer (RX), and the electrode layer 428 may be divided into a plurality of sensing regions; the reflector 421 may serve as the second signal transmission layer 432 and receive the driving signal as a driving electrode layer (TX). In a brief, one of the reflector 421 and the electrode layer 428 serves as the driving electrode layer and the other servers as the sensing electrode layer, or vice versa.

FIG. 4B illustrates a schematic diagram of a display device with a force sensing device according to another embodiment of the invention. Referring to FIG. 4B, in the present embodiment, a display device 400B includes the display layer 410 and the non-display layer 420. A force sensing device 430B is a self-capacitance type force sensing device and includes a reference layer 431B, the signal transmission layer 432B and the deformable layer 424. The signal transmission layer 432B of the self-capacitance type force sensing device 430B is configured to receive a driving signal and a sensing signal as a sensor electrode layer. The reference layer 431B is configured to provide a reference voltage level, such as a ground level. The sensing signal indicates a capacitance difference between the signal transmission layer 432B and the reference layer 431B generated when a force is applied to the display device 400B. The deformable layer 424 is disposed on the upper surface S2 of the signal transmission layer 431B. The display device 400B of the present embodiment is similar to the display device 400A depicted in FIG. 4A, and the main difference therebetween, for example, lies in that the electrode layer 428 serves as the reference layer (REF), and the reflector 421 serves as the signal transmission layer 432B and receiving the driving signal and receiving the sensing signal, as a sensor electrode layer (SX) and may be divided into a plurality of sensing regions. Besides, the structure of the display device 400B described in this embodiment of the invention is sufficiently taught, suggested, and embodied in the embodiments illustrated in FIG. 1A to FIG. 4A, and therefore no further description is provided herein. In another embodiment, the electrode layer 428 may serve as the signal transmission layer 432B and receives the driving signal and the sensing signal, as a sensor electrode layer (SX), and the electrode layer 428 may be divided into a plurality of sensing regions; the reflector 421 may serves as the reference layer 431B (REF) providing a reference voltage level. When the force is applied to the display device 400B, the deformable layer 424 is deformed, and a capacitance between the signal transmission layer 432B and the reference layer 431B may change. A sensing signal indicating capacitance difference information is generated and received by the signal transmission layer 432B.

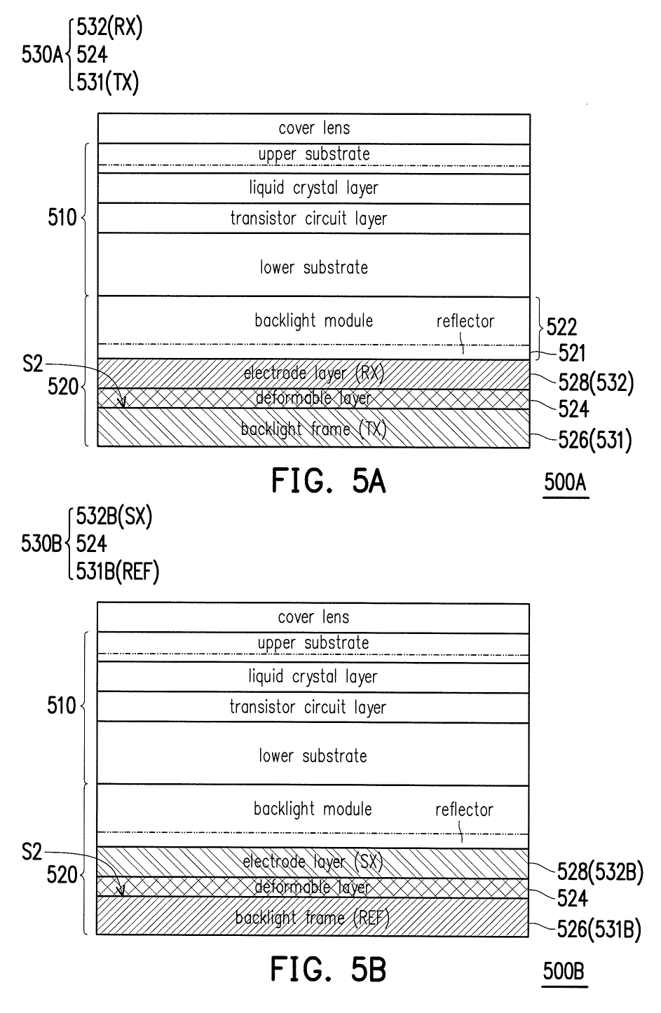

FIG. 5A illustrates a schematic diagram of a display device with a force sensing device according to another embodiment of the invention. Referring to FIG. 1B and FIG. 5A, in the present embodiment, a display device 500A includes a display layer 510 and a non-display layer 520, and a force sensing device 530A is a mutual capacitance type force sensing device and includes the first signal transmission layer 531, the second signal transmission layer 532 and the deformable layer 524. The first signal transmission layer 531 and the second signal transmission layer 532 are disposed inside the non-display layer 520. In the present embodiment, the driving type of the display layer 510 may be the horizontal electrical field driving or the vertical electrical field driving. The deformable layer 524 is disposed on an upper surface S2 of the first signal transmission layer 531. The display device 500A of the present embodiment is similar to the display device 400A depicted in FIG. 4A, and the main difference therebetween, for example, lies in that the deformable layer 524 is disposed between an electrode layer 528 and a backlight frame 526. The electrode layer 528 is disposed above the deformable layer 524. In the present embodiment, the electrode layer 528 serves as the second signal transmission layer 532, and receives the sensing signal, and the backlight frame 526 serves as the first signal transmission layer 531, and receives the driving signal. In other words, the electrode layer 528 servers as a sensing electrode layer (RX) and the backlight frame 526 serves as a driving electrode layer (TX). The electrode layer 528 served as the sensing electrode layer may be divided into a plurality of sensing regions. Besides, the structure of the display device 500A described in this embodiment of the invention is sufficiently taught, suggested, and embodied in the embodiments illustrated in FIG. 1A to FIG. 4B, and therefore no further description is provided herein. In another embodiment, the sensing signal is transmitted in the first signal transmission layer 531 and the driving signal is transmitted in the second signal transmission layer 532; in other words, the backlight frame 526 may serve as the first signal transmission layer 531 and receive the sensing signal as a sensing electrode layer (RX), and the backlight frame 526 may be divided into a plurality of sensing regions; the electrode layer 528 may serve as the second signal transmission layer 532 and receive the driving signal as a driving electrode layer (TX). In a brief, one of the electrode layer 528 and the backlight frame 526 serves as the driving electrode layer and the other servers as the sensing electrode layer, or vice versa.

FIG. 5B illustrates a schematic diagram of a display device with a force sensing device according to another embodiment of the invention. Referring to FIG. 5A and FIG. 5B, in the present embodiment, a display device 500B includes the display layer 510 and the non-display layer 520, and a force sensing device 530B is a self-capacitance type force sensing device and includes a reference layer 531B, the signal transmission layer 532 and the deformable layer 524. The signal transmission layer 532B of the self-capacitance type force sensing device 530B is configured to receive a driving signal and a sensing signal as a sensor electrode layer. The reference layer 531B is configured to provide a reference voltage level, such as a ground level. The sensing signal indicates a capacitance difference between the signal transmission layer 532B and the reference layer 531B generated when a force is applied to the display device 500B. The deformable layer 524 is disposed on the upper surface S2 of the signal transmission layer 531B. The display device 500B of the present embodiment is similar to the display device 500A depicted in FIG. 5A, and the main difference therebetween, for example, lies in that the backlight frame 526 serves as serves as the reference layer (REF), and the electrode layer 528 serves as the signal transmission layer 532B receiving the driving signal and receiving the sensing signal, as a sensor electrode layer (SX) and may be divided into a plurality of sensing regions. Besides, the structure of the display device 500B described in this embodiment of the invention is sufficiently taught, suggested, and embodied in the embodiments illustrated in FIG. 1A to FIG. 5A, and therefore no further description is provided herein. In another embodiment, the backlight frame 526 may serve as the signal transmission layer 532B and receives the driving signal and the sensing signal, as a sensor electrode layer (SX), and the backlight frame 526 may be divided into a plurality of sensing regions; the electrode layer 528 may serves as the reference layer (REF) providing a reference voltage level. When the force is applied to the display device 500B, the deformable layer 524 is deformed, and a capacitance between the signal transmission layer 532B and the reference layer 531B may change. A sensing signal indicating capacitance difference information is generated and received by the signal transmission layer 532B.

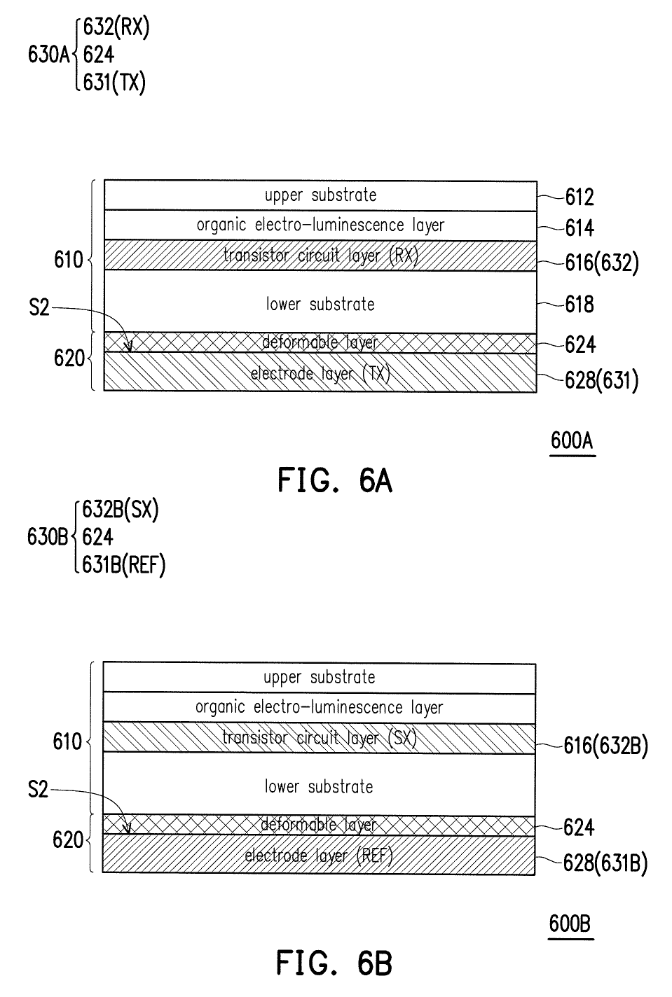

FIG. 6A illustrates a schematic diagram of a display device with a force sensing device according to another embodiment of the invention. Referring to FIG. 6A, the display device 600A of the present embodiment includes a display layer 610 and a non-display layer 620, and a force sensing device 630A is a mutual capacitance type force sensing device and includes a first signal transmission layer 631, a second signal transmission layer 632 and a deformable layer 624. The display layer 610 is disposed above the non-display layer 620. The display layer 610 is configured to display an image. The force sensing device 630A is configured to sense a force applied to the display device 600A.

In the present embodiment, the display layer 610 includes an upper substrate 612, an organic electro-luminescence layer 614, a transistor circuit layer 616 and a lower substrate 618. The transistor circuit layer 616 is disposed above the lower substrate 618. The organic electro-luminescence layer 614 is disposed above the transistor circuit layer 616. The upper substrate 612 is disposed above the organic electro-luminescence layer 614. The upper substrate 612 and the lower substrate 618 may be glass substrates or light-transmissive substrates, and the invention is not limited thereto. For a white OLED device, a color filter layer (not shown in FIG. 6A) may be formed on the upper substrate 612 and disposed between the upper substrate 612 and the organic electro-luminescence layer 614. For an R/G/B OLED device, a color filter layer is unnecessary and can be omitted, and in such a case the upper substrate 612 may be adopted for encapsulation. In the present embodiment, the display layer 610 may further include other suitable layers such as a cathode layer disposed above the organic electro-luminescence layer 614 and an anode layer disposed above the transistor circuit layer 616.

In the present embodiment, the non-display layer 620 includes an electrode layer 628 and the deformable layer 624. The deformable layer 624 is disposed above the electrode layer 628.

In the present embodiment, the first signal transmission layer 631 is disposed inside the non-display layer 620. The second signal transmission layer 632 is disposed above the first signal transmission layer 631 and is disposed inside the display layer 610. In the present embodiment, the transistor circuit layer 616 serves as the second signal transmission layer 632, and receives a sensing signal. The sensing signal is transmitted in the second signal transmission layer 632. The driving signal drives the force sensing device 630A to sense the force applied to the display device 600A. In the present embodiment, the force sensing device 630A is driven to sense the force applied to the display device 600A, and generates a sensing signal. The electrode layer 628 serves as the first signal transmission layer 631, and receives the driving signal. The driving signal is transmitted in the first signal transmission layer 631. In other words, the transistor circuit layer 616 servers as a sensing electrode layer (RX), and the electrode layer 628 serves as a driving electrode layer (TX). In the present embodiment, the sensing signal may be transmitted in common electrodes of the transistor circuit layer 616.

In the present embodiment, the deformable layer 624 is disposed on an upper surface S2 of the first signal transmission layer 631, i.e. the electrode layer 628. In the present embodiment, the deformable layer 624 is disposed between the display layer 610 and the non-display layer 620. The deformable layer 624 may be deformed by the force applied to the display device 600A. The deformable layer 624 may be selected from an air gap, an elastic cushion layer, and any other suitable means which is deformed when force is applied to the display device 600A.

In another embodiment, the sensing signal is transmitted in the first signal transmission layer 631 and the driving signal is transmitted in the second signal transmission layer 632; in other words, the electrode layer 628 may serve as the first signal transmission layer 631 and receive the sensing signal as a sensing electrode layer (RX), and may be divided into a plurality of sensing regions; the transistor circuit layer 616 may serve as the second signal transmission layer 632 and receive the driving signal as a driving electrode layer (TX), and the driving signal may be transmitted in the common electrodes, source line electrode, gate line electrode, or other electrically conductive lines of the transistor circuit layer 616. In a brief, one of the transistor circuit layer 616 and the electrode layer 628 serves as the driving electrode layer and the other servers as the sensing electrode layer, or vice versa.

FIG. 6B illustrates a schematic diagram of a display device with a force sensing device according to another embodiment of the invention. Referring to FIG. 6A and FIG. 6B, in the present embodiment, a force sensing device 630B is a self-capacitance type force sensing device and includes a reference layer 631B, the signal transmission layer 632B and the deformable layer 624. The signal transmission layer 632B of the self-capacitance type force sensing device 630B is configured to receive a driving signal and a sensing signal as a sensor electrode layer. The reference layer 631B is configured to provide a reference voltage level, such as a ground level. The sensing signal indicates a capacitance difference between the signal transmission layer 632B and the reference layer 631B generated when a force is applied to the display device 600B. The display device 600B of the present embodiment is similar to the display device 600A depicted in FIG. 6A, and the main difference therebetween, for example, lies in that the electrode layer 628 serves as the reference layer (REF), and the transistor circuit layer 616 serves as the signal transmission layer 632B receiving the driving signal and receiving the sensing signal, as a sensor electrode layer (SX). In the present embodiment, the driving signal and the sensing signal may be transmitted in common electrode of the transistor circuit layer 616. Besides, the structure of the display device 600B described in this embodiment of the invention is sufficiently taught, suggested, and embodied in the embodiment illustrated in FIG. 6A, and therefore no further description is provided herein. In another embodiment, the electrode layer 628 may serve as the signal transmission layer 632B and receives the driving signal and the sensing signal, as a sensor electrode layer (SX), and may be divided into a plurality of sensing regions; the transistor circuit layer 616 may serves as the reference layer (REF) providing a reference voltage level. When the force is applied to the display device 600B, the deformable layer 624 is deformed, and a capacitance between the signal transmission layer 632B and the reference layer 631B may change. A sensing signal indicating capacitance difference information is generated and received by the signal transmission layer 632B.

In summary, in the exemplary embodiments of the invention, the force sensing device is a force sensing device of mutual-capacitance type or a force sensing device of self-capacitance type. For the force sensing device of mutual-capacitance type, at least one of the first signal transmission layer and the second signal transmission layer is not disposed inside the display layer. The first signal transmission layer is an electrically conductive layer selected from layers of the non-display layer. The second signal transmission layer is an electrically conductive layer selected from layers of the non-display layer or from layers of the display layer. For the force sensing device of self-capacitance type, at least one of the signal transmission layer and the reference layer is not disposed inside the display layer. In other words, when the signal transmission layer for receiving the driving signal and the sensing signal is an electrically conductive layer selected from layers of the non-display layer, the reference layer is an electrically conductive layer selected from either the non-display layer or the display layer; and in another case, when the signal transmission layer for receiving the driving signal and the sensing signal is an electrically conductive layer selected from the display layer, the reference layer is an electrically conductive layer selected from the non-display layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display device with a force sensing device, comprising:
a display layer, configured to display an image; and
a non-display layer, disposed below the display layer; and the non-display layer comprising:
a first signal transmission layer; and
a deformable layer, disposed on a surface of the first signal transmission layer,
wherein the force sensing device comprises the deformable layer, the first signal transmission layer and a second signal transmission layer, the second signal transmission layer is disposed above the first signal transmission layer, and one of the first signal transmission layer and the second signal transmission layer receives a driving signal and the other of the first signal transmission layer and the second signal transmission layer receives a sensing signal.

2. The display device with the force sensing device according to claim 1, wherein the second signal transmission layer is disposed inside one of the display layer and the non-display layer.

3. The display device with the force sensing device according to claim 1, wherein the deformable layer is disposed inside the non-display layer or between the display layer and the non-display layer.

4. The display device with the force sensing device according to claim 1, wherein the display layer comprises: a substrate; and a transistor circuit layer disposed above the substrate, wherein the transistor circuit layer serves as the second signal transmission layer.

5. The display device with the force sensing device according to claim 4, wherein the display layer comprises a liquid crystal layer, and the display layer is driven by a horizontal electrical field.

6. The display device with the force sensing device according to claim 4, wherein the non-display layer comprises: a backlight frame; and a backlight module disposed above the backlight frame and comprising a reflector, wherein the first signal transmission layer is the backlight frame or the reflector.

7. The display device with the force sensing device according to claim 6, wherein the deformable layer is disposed between the reflector and the backlight frame.

8. The display device with the force sensing device according to claim 4, wherein the non-display layer further comprises: a backlight frame which the first signal transmission layer is disposed above; and a backlight module disposed above the first signal transmission layer and comprising a reflector.

9. The display device with the force sensing device according to claim 8, wherein the deformable layer is disposed between the substrate and the backlight module or between the reflector and the first signal transmission layer.

10. The display device with the force sensing device according to claim 1, wherein the display layer further comprises one of a liquid crystal layer and an organic electro-luminescence layer.

11. The display device with the force sensing device according to claim 1, wherein the non-display layer comprises: a backlight frame; an electrode layer disposed above the backlight frame; and a backlight module disposed above the electrode layer and comprising a reflector, wherein the first signal transmission layer and the second signal transmission layer are selected from two of the reflector, the electrode layer and the backlight frame.

12. The display device with the force sensing device according to claim 11, wherein the electrode layer serves as the first signal transmission layer, the reflector serves as the second signal transmission layer, and the deformable layer is disposed between the reflector and the electrode layer.

13. The display device with the force sensing device according to claim 11, wherein the electrode layer serves as the first signal transmission layer, the reflector serves as the second signal transmission layer, and the deformable layer is disposed between the electrode layer and the backlight frame.

14. A display device with a force sensing device, comprising:
a display layer, configured to display an image; and
a non-display layer, disposed below the display layer, and comprising a deformable layer,
wherein the force sensing device comprises the deformable layer, a signal transmission layer and a reference layer, the deformable layer is disposed on a surface of the signal transmission layer, the signal transmission layer is configured to receive a driving signal and receive a sensing signal, and the reference layer is configured to provide a reference voltage level.

15. The display device with the force sensing device according to claim 14, wherein the signal transmission layer is disposed inside one of the display layer and the non-display layer.

16. The display device with the force sensing device according to claim 14, wherein the deformable layer is disposed inside the non-display layer or between the display layer and the non-display layer.

17. The display device with the force sensing device according to claim 14, wherein the reference layer is disposed inside one of the display layer and the non-display layer.

18. The display device with the force sensing device according to claim 14, wherein the display layer comprises: a substrate; and a transistor circuit layer disposed above the substrate, wherein the transistor circuit layer serves as the signal transmission layer.

19. The display device with the force sensing device according to claim 18, wherein the display layer comprises a liquid crystal layer, and the display layer is driven by a horizontal electrical field.

20. The display device with the force sensing device according to claim 18, wherein the non-display layer comprises: a backlight frame; and a backlight module disposed above the backlight frame and comprising a reflector, wherein the backlight frame or the reflector servers as the reference layer.

21. The display device with the force sensing device according to claim 20, wherein the deformable layer is disposed between the reflector and the backlight frame.

22. The display device with the force sensing device according to claim 18, wherein the non-display layer further comprises: a backlight frame which the reference layer is disposed above; and a backlight module disposed above the reference layer and comprising a reflector.

23. The display device with the force sensing device according to claim 22, wherein the deformable layer is disposed between the substrate and the backlight module or between the reflector and the reference layer.

24. The display device with the force sensing device according to claim 14, wherein the display layer further comprises one of a liquid crystal layer and an organic electro-luminescence layer.

25. The display device with the force sensing device according to claim 14, wherein the non-display layer comprises: a backlight frame; an electrode layer disposed above the backlight frame; and a backlight module disposed above the electrode layer and comprising a reflector, wherein the reference layer and the signal transmission layer are two of the reflector, the electrode layer and the backlight frame.

26. The display device with the force sensing device according to claim 25, wherein the electrode layer serves as the reference layer, the reflector serves as the signal transmission layer, and the deformable layer is disposed between the reflector and the electrode layer.

27. The display device with the force sensing device according to claim 26, wherein the electrode layer serves as the reference layer, the reflector serves as the signal transmission layer, and the deformable layer is disposed between the electrode layer and the backlight frame.
